(19) United States
(12) Patent Application Publication
(10) Pub. No.: US 2025/0040414 A1
(43) Pub. Date: Jan. 30, 2025

(54) DISPLAY DEVICE COMPRISING COVER LAYER AND COVER LAYER FOR DISPLAY DEVICE

(71) Applicant: Samsung Display Co., LTD., Yongin-si (KR)

(72) Inventors: Chae Kyeong LEE, Yongin-si (KR); Won Jong BAEK, Yongin-si (KR); Jeong Seok LEE, Yongin-si (KR)

(73) Assignee: Samsung Display Co., LTD., Yongin-si (KR)

(21) Appl. No.: 18/656,946

(22) Filed: May 7, 2024

(30) Foreign Application Priority Data
Jul. 25, 2023 (KR) 10-2023-0096942

(51) Int. Cl. H10K 59/80; G02F 1/1335

(52) U.S. Cl. CPC H10K 59/8791; G02F 1/133502

(57) ABSTRACT

A cover layer for a display device, the cover layer including a sapphire substrate; a first cover layer disposed on the sapphire substrate, the first cover layer including MgF₂, the first cover layer having a thickness in a range of about 16 nm to about 26 nm; a second cover layer disposed on the first cover layer, the second cover layer including Si₉Al₂O₁₀, the second cover layer having a thickness in a range of about 45 nm to about 70 nm; and a third cover layer disposed on the second cover layer, the third cover layer including perfluorinated polyether (PEPE), the third cover layer having a thickness in a range of about 10 nm to about 45 nm.

### CROSS-REFERENCE TO RELATED APPLICATIONS

This application claims priority under 35 U.S.C. § 119 from Korean Patent Application No. 10-2023-0096942 filed on Jul. 25, 2023 in the Korean Intellectual Property Office, the entire contents of which are incorporated herein by reference.

### BACKGROUND

### 1. Technical Field

The disclosure relates to a display device having a cover layer and a cover layer for a display device.

### 2. Description of the Related Art

With the development of information technologies, the importance of a display device which is a connection medium between a user and information increases.

A structure for improving external visibility may be required in the display device. For example, it may be necessary to control the reflection of external light for improving the external visibility.

### SUMMARY

Embodiments provide a display device having a cover layer and a cover layer for a display device in which the reflection of external light may be controlled so that visibility can be improved.

Embodiments also provide a display device having a cover layer and a cover layer in which an excellent color shift characteristics (i.e., ΔE or reflective color sense) may be provided, so that the reliability of display quality can be improved.

In accordance with an aspect of the disclosure, there may be provided a cover layer that may include a sapphire substrate; a first cover layer disposed on the sapphire substrate, the first cover layer including MgF₂, the first cover layer having a thickness in a range of about 16 nm to about 26 nm; a second cover layer disposed on the first cover layer, the second cover layer including Si₉Al₂O₁₀, the second cover layer having a thickness in a range of about 45 nm to about 70 nm; and a third cover layer disposed on the second cover layer, the third cover layer including perfluorinated polyether (PEPE), the third cover layer having a thickness in a range of about 10 nm to about 45 nm.

A surface of the first cover layer may be in contact with the sapphire substrate, another surface of the first cover layer may be in contact with a surface of the second cover layer. Another surface of the second cover layer may be in contact with a surface of the third cover layer.

The first cover layer may include a crystalline structure including MgF₂.

A refractive index of the first cover layer may be in a range of about 1.24 to about 1.52.

The thickness of the first cover layer may be in a range of about 18 nm to about 24 nm.

The second cover layer may couple the first cover layer to the third cover layer.

A refractive index of the second cover layer may be in a range of about 1.33 to about 1.63.

The thickness of the second cover layer may be in a range of about 52 nm to about 64 nm.

Another surface of the third cover layer may be exposed.

A refractive index of the third cover layer may be in a range of about 1.05 to about 1.59.

The thickness of the third cover layer may be in a range of about 32 nm to about 40 nm.

A refractive index of the sapphire substrate may be about 1.77. A refractive index of the first cover layer may be about 1.38, a refractive index of the second cover layer may be about 1.48, and a refractive index of the third cover layer may be about 1.32.

In accordance with another aspect of the disclosure, there may be provided a display device that may include a light-emitting-element layer including a light emitting element emitting light; and a cover layer disposed on the light-emitting-element layer, wherein the cover layer may include a sapphire substrate; a first cover layer disposed on the sapphire substrate, the first cover layer including MgF₂, the first cover layer having a thickness in a range of about 16 nm to about 26 nm; a second cover layer disposed on the first cover layer, the second cover layer including Si₉Al₂O₁₀, the second cover layer having a thickness in a range of about 45 nm to about 70 nm; and a third cover layer disposed on the second cover layer, the third cover layer including perfluorinated polyether (PEPE), the third cover layer having a thickness in a range of about 10 nm to about 45 nm.

A sum of the thicknesses of the first to third cover layers may be in a range of about 80 nm to about 130 nm.

A refractive index of the sapphire substrate may be in a range of about 1.60 to about 1.95.

The cover layer may have a transmittance of at least about 92% for 550 nm light and a reflectivity of less than about 8.50% for 550 nm light.

### BRIEF DESCRIPTION OF THE DRAWINGS

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic sectional view illustrating a display device in accordance with the embodiment of the disclosure.

FIG. 3 is a schematic sectional view illustrating a cover layer in accordance with the embodiment of the disclosure.

### DETAILED DESCRIPTION OF THE EMBODIMENTS

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The present disclosure generally relates to a display device having a cover layer and a cover layer for a display device. Hereinafter, a display device having a cover layer and a cover layer for a display device in accordance with an embodiment of the present disclosure will be described with reference to the accompanying drawings.

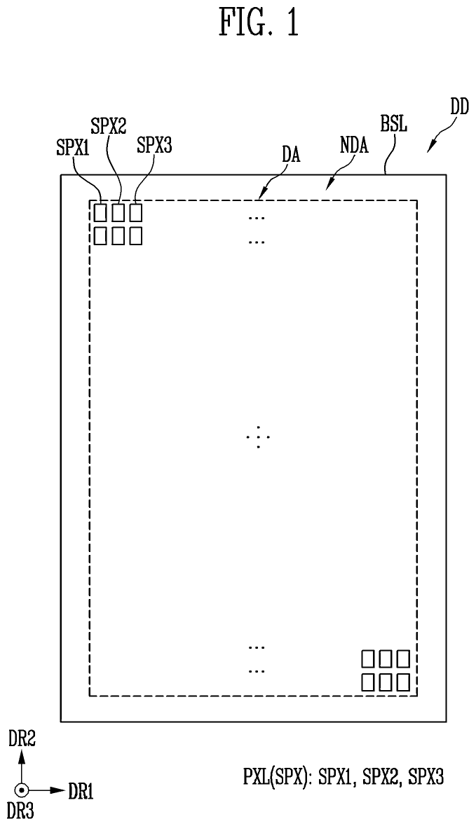

FIG. 1 is a schematic plan view illustrating a display device in accordance with an embodiment of the disclosure.

Referring to FIG. 1, the display device DD may include a base layer BSL and pixels PXL arranged on the base layer BSL. Although not shown in the drawing, the display device DD may further include a driving circuit part (e.g., a scan driver and a data driver) for driving the pixels PXL, lines, and pads.

The display device DD (or the base layer BSL) may include a display area DA and a non-display area NDA. The non-display area NDA may mean an area except the display area DA. The non-display area NDA may surround at least a portion of the display area DA.

The base layer BSL may form a base surface of the display device DD. The base layer BSL may be a rigid or a flexible substrate or a film. For example, the base layer BSL may be a rigid substrate made of glass or tempered glass, a flexible substrate (or thin film) made of a plastic or metal material, or at least one insulating layer. The material and/or property of the base layer BSL may not be particularly limited. In an embodiment, the base layer BSL may be substantially transparent. The term “substantially transparent” may mean that light can be transmitted with a transmittance (e.g., a predetermined or selectable transmittance) or more. In an embodiment, the base layer BSL may be translucent or opaque. Also, the base layer BSL may include a reflective material in some embodiments.

The display area DA may mean an area in which the pixels PXL may be disposed. The non-display area NDA may mean an area in which the pixels PXL may not be disposed. The driving circuit, the lines, and the pads, which may be electrically connected to the pixels PXL of the display area DA, may be disposed in the non-display area NDA.

In accordance with an embodiment, the pixels PXL (or sub-pixels SPX) may be arranged according to a stripe arrangement structure, a PenTile® arrangement structure, or the like. However, the disclosure may not be limited thereto, and various embodiments may be applied in the disclosure.

In accordance with an embodiment, the pixel PXL (or the sub-pixels SPX) may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. At least a first sub-pixel SPXL1, at least a second sub-pixel SPXL2, and at least a third sub-pixel SPXL3 may constitute a pixel part capable of emitting lights of various colors.

For example, each of the first sub-pixel SPXL1, the second sub-pixel SPXL2, and the third sub-pixel SPXL3 may emit light of one color. For example, the first sub-pixel SPXL1 may be a red pixel emitting light of red (e.g., a first color), the second sub-pixel SPXL2 may be a green pixel emitting light of green (e.g., a second color), and the third sub-pixel SPXL3 may be a blue pixel emitting light of blue (e.g., a third color). In accordance with an embodiment, a number of second sub-pixels SPXL2 may be greater than a number of first sub-pixels SPXL1 and a number of third sub-pixels SPXL3. However, the color, kind, and/or number of first, second, and third sub-pixels SPXL1, SPXL2, and SPXL3 constituting each pixel part may not be limited to a specific example.

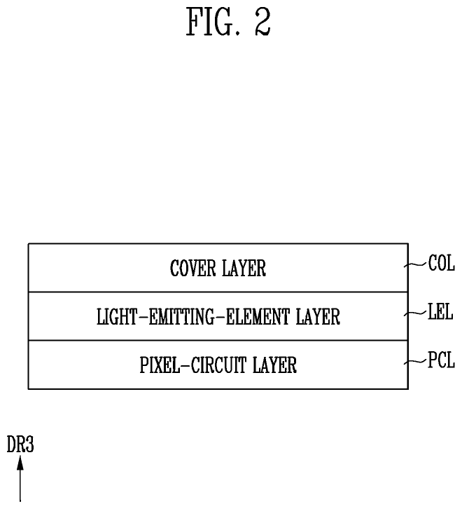

FIG. 2 is a schematic sectional view illustrating a display device in accordance with the embodiment of the disclosure.

Referring to FIG. 2, the display device DD may include a pixel-circuit layer PCL (e.g., a backplane layer), a light-emitting-element layer LEL, and a cover layer COL.

The pixel-circuit layer PCL may be a layer including a pixel circuit for driving a pixel PXL formed by the light-emitting-element layer LEL (or a light emitting element included in the light-emitting-element layer LEL). The pixel-circuit layer PCL may include a base layer BSL, conductive layers for forming pixel circuits, and insulating layers disposed on the conductive layers.

The light-emitting-element layer LEL may be disposed on the pixel-circuit layer PCL. In some embodiments, the light-emitting-element layer LEL may include a light emitting element. In some embodiments, the light emitting element may include an Organic Light Emitting Diode (OLED). In some embodiments, the light emitting element may include an inorganic light emitting element including an inorganic material. In some embodiments, the light-emitting-element layer LEL may include a Liquid Crystal Display (LCD). However, the disclosure may not be necessarily limited thereto.

The cover layer COL may be disposed on the light-emitting-element layer LEL. The cover layer COL may allow light emitted from the light-emitting-element layer LEL to be transmitted through itself to an outside to be viewed. The cover layer COL may have a coating structure.

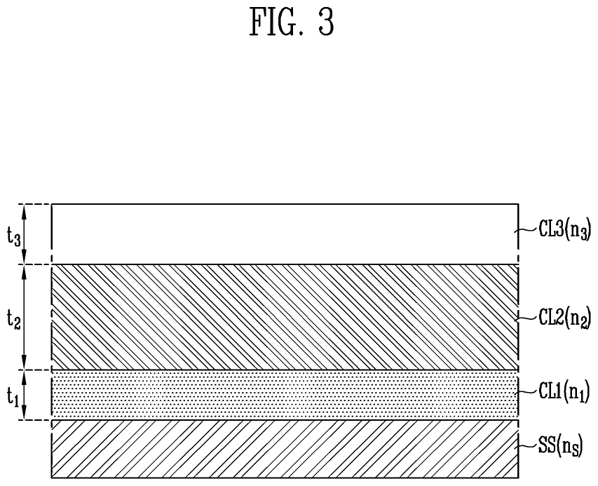

The cover layer COL in accordance with the embodiment of the disclosure will be described in detail later with reference to FIG. 3.

FIG. 3 is a schematic sectional view illustrating a cover layer in accordance with the embodiment of the disclosure.

The cover layer COL in accordance with the embodiment of the disclosure may be characterized by reducing the reflection of external light.

In accordance with an embodiment, the cover layer COL may include a sapphire substrate SS and functional layers on the sapphire substrate SS. For example, the cover layer COL may include the sapphire substrate SS, and a first cover layer CL1, a second cover layer CL2, and a third cover layer CL3, which may be disposed on the sapphire substrate SS.

In some embodiments, the sapphire substrate SS may form a base of the cover layer COL. For example, the first cover layer CL1, the second cover layer CL2, and the third cover layer CL3, which may be disposed on the sapphire substrate SS, may be formed through a Physical Vapor Deposition (PVD) process including sputtering, electron-beam evaporation, thermal evaporation, and an ion assisted deposition (IAD). However, the disclosure may not be limited to a specific example.

In some embodiments, a total thickness of the first to third cover layers CL1, CL2, and CL3 disposed on the sapphire substrate SS may be in a range of about 80 nm to about 130 nm. For example, the first to third cover layers CL1, CL2, and CL3 each having a refractive index may satisfy a thickness range (e.g., a predetermined or selectable thickness range), and accordingly, proper anti-reflection performance can be achieved. This will be described in detail later.

In some embodiments, the sapphire substrate SS may be disposed on an uppermost portion (e.g., a thin film encapsulation layer, a capping layer, or the like) of the light-emitting-element layer LEL.

The sapphire substrate SS may include aluminum oxide (AlₓO_{y}) and include a crystalline structure. As the sapphire substrate SS has a high hardness, the sapphire substrate SS may have a high scratch resistance.

The sapphire substrate SS may have a relatively high refractive index as compared with a general glass substrate. The sapphire substrate SS may have the highest refractive index among the layers forming the cover layer COL.

The sapphire substrate SS may have a substrate refractive index nₛ. The substrate refractive index nₛ may be in a range of about 1.60 to about 1.95. In some embodiments, the substrate refractive index nₛ may be about 1.77. However, the disclosure may not be limited thereto.

Light emitted from the light-emitting-element layer LEL may be transmitted through the sapphire substrate SS. Therefore, as the sapphire substrate SS has a high refractive index, the transmitted light may be distorted.

In accordance with an embodiment, while the sapphire substrate SS may be disposed to have high structural stability (e.g., durability and scratch resistance characteristics), refractive indices and thicknesses of the first cover layer CL1, the second cover layer CL2, and the third cover layer CL3, which may be disposed on the sapphire substrate SS, may be optimized so that the display device can have improved reflection characteristics regarding the reflection of external light while having an excellent or minimal color shift or ΔE characteristics.

The first cover layer CL1 may be disposed on the sapphire substrate SS. The first cover layer CL1 may be disposed between the sapphire substrate SS and the second cover layer CL2.

In some embodiments, a first surface (e.g., a surface) of the first cover layer CL1 may be in contact with the sapphire substrate SS. A second surface (e.g., another surface) of the first cover layer CL1 may be in contact with the second cover layer CL2.

The first cover layer CL1 may have a refractive index n₁. The refractive index n₁ may be included in a range of about 1.24 to about 1.52. In some embodiments, the refractive index n₁ may be about 1.38. However, the disclosure may not be limited thereto.

In some embodiments, a refractive index of each of the layers disclosed in this specification may be defined as a refractive index with respect to light having a wavelength of about 550 nm.

The first cover layer CL1 may include a single layer. However, the disclosure may not be limited thereto.

The first cover layer CL1 may include fluorine. For example, the first cover layer may include MgF₂. In some embodiments, the first cover layer CL1 may include a crystalline structure formed by MgF₂.

The first cover layer CL1 may have a thickness t₁. In some embodiments, the first cover layer CL1 may have a thickness smaller than a thickness of each of the other layers forming the cover layer COL. The first cover layer CL1 may be the thinnest layer in the cover layer.

For example, the thickness t₁ may be smaller than a thickness of the sapphire substrate SS. The thickness t₁ may be smaller than a thickness t₂ of the second cover layer CL2. In some embodiments, the first thickness t₁ may be smaller than a thickness t₃ of the third cover layer CL3.

In some embodiments, the thickness t₁ may be smaller than about 50 nm. The thickness t₁ may be in a range of about 16 nm to about 26 nm. The thickness t₁ may be in a range of about 18 nm to about 24 nm. For example, the thickness t₁ may be about 21 nm.

In some embodiments, the first cover layer CL1 may be a low refractive layer, and may have a relatively low refractive index and reduce the reflection of external light.

Experimentally, in case that the thickness of a low refractive structure may not be sufficiently large, a technical effect of low reflection may not sufficiently occur. The thickness of the first cover layer CL1 can be optimized in relation to the other layers disposed in the cover layer COL, and the reduction of the reflection of external light and the technical effect of improved ΔE characteristics can be maximized.

The second cover layer CL2 may be disposed on the first cover layer CL1. The second cover layer CL2 may be disposed between the first cover layer CL1 and the third cover layer CL3.

In some embodiments, a first surface (e.g., a surface) of the second cover layer CL2 may be in contact with the first cover layer CL1. A second surface (e.g., another surface) of the second cover layer CL2 may be in contact with the third cover layer CL3.

The second cover layer CL2 may have a refractive index n₂. The refractive index n₂ may be in a range of about 1.3 to about 1.6. The refractive index n₂ may be in a range of about 1.33 to about 1.63. In some embodiments, the refractive index n₂ may be about 1.48. However, the disclosure may not be limited thereto.

The second cover layer CL2 may include an additional material that may be mixed with silicon oxide (SiOₓ). In some embodiments, the additional material may include at least one material selected from a group consisting of aluminum (Al), aluminum oxide (AlₓO_{y}) (e.g., Al₂O₃), yttrium (Y), magnesium (Mg), zirconium (Zr), calcium (Ca), barium (Ba), titanium (Ti), tantalum (Ta), molybdenum (Mo), and germanium (Ge).

For example, the second cover layer CL2 may include silicon oxide (SiOₓ) and aluminum oxide (AlOₓ). For example, the second cover layer CL2 may include SiO₂ and Al₂O₃. The SiO₂ and Al₂O₃ in the second cover layer CL2 may exist as a substitutional solid solution. For example, the SiO₂ and Al₂O₃ in the second cover layer CL2 may be substituted for each other to form a structure (e.g., a crystalline structure). Accordingly, Si₉Al₂O₁₀ may be included in the second cover layer CL2.

In some embodiments, the second cover layer CL2 may have a structure in which Al may be included in silicon oxide (SiOₓ), and the Al may be included in a range of about 0.1% to about 20%, which may be expressed as atomic percentages.

The second cover layer CL2 may have the thickness t₂. In some embodiments, the second cover layer CL2 may have a thickness greater than a thickness of each of the other layers disposed on the sapphire substrate SS.

For example, the thickness t₂ may be greater than each of the thickness t₁ of the first cover layer CL1 and the thickness t₃ of the third cover layer CL3.

In some embodiments, the thickness t₂ may be greater than about 25 nm. The thickness t₂ may be in a range of about 45 nm to about 70 nm. The thickness t₂ may be in a range of about 51 nm to about 66 nm. The thickness t₂ may be in a range of about 52 nm to about 64 nm. For example, the thickness t₂ may be about 58 nm.

In some embodiments, the second cover layer CL2 may be an adhesive layer, and may allow the first cover layer CL1 and the third cover layer CL3, which may be adjacent to each other, to be adhered to each other.

The thickness of the second cover layer CL2 can be optimized in relation to the other layers disposed in the cover layer COL, and the reduction of the reflection of external light and the technical effect of reduced or minimal color shift (i.e., ΔE characteristics) while adhesion performance may be sufficiently ensured.

The third cover layer CL3 may be disposed on the second cover layer CL2.

In some embodiments, a first surface (e.g., a surface) of the third cover layer CL3 may be in contact with the second cover layer CL2. A second surface (e.g., another surface) of the third cover layer CL3 may be exposed.

The third cover layer CL3 may have a refractive index n₃. The refractive index n₃ may be in a range about of 1.05 to about 1.59. In some embodiments, the refractive index n₃ may be about 1.32. However, the disclosure may not be limited thereto.

The third cover layer CL3 may have the thickness t₃. In some embodiments, the third cover layer CL3 may correspond to an average thickness of the other layers disposed on the sapphire substrate SS.

For example, the thickness t₃ of the third cover layer CL3 may be greater than the thickness t₁ of the first cover layer CL1. The thickness t₃ of the third cover layer CL3 may be smaller than the second thickness t₂ of the second cover layer CL2.

In some embodiments, the thickness t₃ of the third cover layer CL3 may be in a range of about 10 nm to about 40 nm. The thickness t₃ may be in a range of about 10 nm to about 45 nm. In some embodiments, the thickness t₃ may be greater than about 30 nm. The thickness t₃ may be in a range of about 28 nm to about 43 nm. The thickness may be in a range of about 32 nm to about 40 nm. For example, the thickness t₃ may be about 36 nm.

The third cover layer CL3 may include a material for implementing an anti-reflection function. For example, the third cover layer CL3 may include perfluorinated polyether (PEPE). In some embodiments, the third cover layer CL3 may include a material in which a siloxane linker and two or more silyl groups may be coupled to a polymer including the PEPE. In case that the third cover layer CL3 includes the PEPE, excellent anti-fingerprint characteristics can be implemented. However, the disclosure may not be necessarily limited thereto.

The thickness t₃ of the third cover layer CL3 can be optimized in relation to the other layers forming the cover layer COL, and the reduction of the reflection of external light and the technical effect of reduced color shift can be achieved while anti-fingerprint characteristics may be ensured.

In accordance with an embodiment, the cover layer COL may have a transmittance of about 92.5% or more with respect to light having a wavelength of about 550 nm. In some embodiments, the cover layer COL may have a transmittance of about 91.2% or more with respect to light having a wavelength of about 550 nm.

In accordance with an embodiment, the cover layer COL may have a reflectivity of about 8.5% or less with respect to light having a wavelength of about 550 nm. In some embodiments, the cover layer COL may have a reflectivity of about 8.4% or less with respect to light having a wavelength of about 550 nm.

Hereinafter, the disclosure will be described in more detail based on embodiments and comparative examples. However, the following embodiments and comparative examples are only examples for describing in more detail the disclosure, and the disclosure may not be limited by the following embodiments and comparative examples.

A first cover layer CL1 including MgF₂, a second cover layer CL2 including Si₉Al₂O₁₀, and a third cover layer CL3 including PEPE were sequentially stacked on the sapphire substrate SS using electronic-beam evaporation, and a cover layer COL in accordance with an embodiment was manufactured.

In the cover layer COL in accordance with the embodiment, the first cover layer CL1 was formed to have a thickness of about 21 nm, the second cover layer CL2 was formed to have a thickness of about 58 nm, and the third cover layer CL3 was formed to have a thickness of about 36 nm.

In order to more thoroughly ensure the reliability of an experimental result, cover layers COL in accordance with three embodiments were manufactured using a same manufacturing method. Hereinafter, the manufactured cover layers COL may be respectively designated as Embodiment 1, Embodiment 2, and Embodiment 3.

A cover layer in accordance with comparative examples were manufactured using the same method as the embodiments, except for a thickness of each of a first layer CL1, a second cover layer CL2, and a third cover layer CL3.

In the cover layer in accordance with the comparative examples, the first cover layer CL1 was formed to have a thickness of about 70 nm, the second cover layer CL2 was formed to have a thickness of about 15 nm, and the third cover layer CL3 was formed to have a thickness of about 36 nm.

Similar to the manufacturing of the cover layers COL in accordance with the above-described embodiments, in order to more thoroughly ensure the reliability of an experimental result, multiple cover layers in accordance with three comparative examples were manufactured using a same manufacturing method. Hereinafter, the manufactured cover layers may be respectively designated as Comparative example 1, Comparative example 2, and Comparative example 3.

An experiment of measuring color shifts (i.e., delta E or ΔE) of the cover layers manufactured in accordance with the embodiments 1 to 3 and the comparative examples 1 to 3 was performed.

In this experiment, a D65 light source (i.e., standard daylight illuminant) as one of International Commission on Illumination (CIE) light sources was used. In case that the light source was normal incident onto each of the cover layers with respect to the cover layers, a color coordinate position of recognized light was set to a reference position. A color coordinate position was calculated in case that the light source was incident onto each of the cover layers at an incident illumination angle in a range of about 0 degree to about 60 degrees, and color shift data was calculated based on the calculated color coordinate positions. A color shift may be a numerical value determined based on the reference position, and means a difference between a calculated (or intended) color coordinate and a viewed color coordinate as the reference position. An apparatus used in this experiment may be a spectrophotometer (Model name: CM-3700A) manufactured by Minolta Co., Ltd.

TABLE 1

| | Color coordinate in case | |
|---|---|---|
| | that light source is | |
| | incident at incident | |
| Classification | illumination angle | Color shift |
| Embodiment 1 | (1.14, −0.62) | 1.3 |
| Embodiment 2 | (1.11, −0.4) | 1.18 |
| Embodiment 3 | (1.19, −0.5) | 1.29 |
| Comparative example 1 | (0.77, −4.35) | 4.42 |
| Comparative example 2 | (1.32, −4.33) | 4.53 |
| Comparative example 3 | (1.18, −3.41) | 3.61 |

Referring to Table 1, in the case of the cover layer COL in accordance with the embodiments, it can be seen that color shift characteristics are superior as compared with the cover layers in accordance with the comparative examples. Thus, according to the cover layers COL in accordance with the embodiments, a display device DD having excellent display quality according to a viewing angle can be provided.

An experiment for measuring transmittance characteristics of the cover layers COL manufactured in accordance with the embodiments 1 to 3 was performed. In order to check a transmittance improvement effect of the cover layers in accordance with the embodiments, the same experiment was performed using a sapphire substrate on which the cover layers COL were not disposed. Hereinafter, the sapphire substrate was designated as a reference.

In this experiment, light having a wavelength of about 550 nm was applied to each of the cover layers COL and the sapphire substrate as the reference to face the top from the sapphire substrate, and intensities of transmitted light were measured. Accordingly, ratios of the intensities of the transmitted light with respect to intensities of the applied light were calculated. An apparatus used in this experiment is a spectrophotometer (Model name: CM-3700A) manufactured by Minolta Co., Ltd.

TABLE 2

| Classification | Transmittance (%) |
|---|---|
| Embodiment 1 | 90.99 |
| Embodiment 2 | 91.14 |
| Embodiment 3 | 91.15 |
| Reference | 85.31 |

Referring to Table 2, in case that the cover layers COL in accordance with the embodiments are provided on the sapphire substrate, it can be seen that transmittance characteristics are superior compared with a case where the cover layer COL is not provided.

An experiment for measuring reflectivity of the cover layers COL manufactured in accordance with the embodiments 1 to 3 was performed. In order to check reflectance improvement effect of the cover layers in accordance with the embodiments, a same experiment was performed using a sapphire substrate on which the cover layer COL is not disposed. Hereinafter, the sapphire substrate was designated as a reference.

In this experiment, light having a wavelength of about 550 nm was applied to each of the cover layers COL and the sapphire substrate as the reference to face an upper surface, and intensities of reflected light were measured. Accordingly, ratios of the intensities of the reflected light with respect to intensities of the applied light were calculated. An apparatus used in this experiment is a spectrophotometer (Model name: CM-3700A) manufactured by Minolta Co., Ltd.

TABLE 3

| Classification | Reflectivity (%) |
|---|---|
| Embodiment 1 | 8.37 |
| Embodiment 2 | 8.39 |
| Embodiment 3 | 8.39 |
| Reference | 14.41 |

Referring to Table 3, in case that the cover layers COL in accordance with the embodiments are provided on the sapphire substrate, it can be seen that reflectivity characteristics are superior compared with a case where the cover layer COL is not provided.

In summary, in accordance with the embodiments of the disclosure, the display device DD can be implemented in which color shift characteristics can be remarkably improved, while the transmittance and reflectivity characteristics may also be improved.

In accordance with the disclosure, there can be provided a display device having a cover layer and a cover layer in which the reflection of external light may be controlled, so that visibility can be improved.

In accordance with the disclosure, there can be provided a display device having a cover layer and a cover layer in which an excellent color shift (ΔE) characteristics may be provided, so that the reliability of display quality can be improved.

Example embodiments have been disclosed herein, and although specific terms may be employed, they may be used and may be to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A cover layer, comprising:
a sapphire substrate;
a first cover layer disposed on the sapphire substrate, the first cover layer including MgF₂, the first cover layer having a thickness in a range of about 16 nm to about 26 nm;
a second cover layer disposed on the first cover layer, the second cover layer including Si₉Al₂O₁₀, the second cover layer having a thickness in a range of about 45 nm to about 70 nm; and
a third cover layer disposed on the second cover layer, the third cover layer including perfluorinated polyether (PEPE), the third cover layer having a thickness in a range of about 10 nm to about 45 nm.

2. The cover layer of claim 1, wherein
a surface of the first cover layer is in contact with the sapphire substrate,
another surface of the first cover layer is in contact with a surface of the second cover layer, and
another surface of the second cover layer is in contact with a surface of the third cover layer.

3. The cover layer of claim 1, wherein the first cover layer includes a crystalline structure comprising MgF₂.

4. The cover layer of claim 1, wherein a refractive index of the first cover layer is in a range of about 1.24 to about 1.52.

5. The cover layer of claim 1, wherein the thickness of the first cover layer is in a range of about 18 nm to about 24 nm.

6. The cover layer of claim 1, wherein the second cover layer couples the first cover layer to the third cover layer.

7. The cover layer of claim 1, wherein a refractive index of the second cover layer is in a range of about 1.33 to about 1.63.

8. The cover layer of claim 1, wherein the thickness of the second cover layer is in a range of about 52 nm to about 64 nm.

9. The cover layer of claim 1, wherein another surface of the third cover layer is exposed.

10. The cover layer of claim 1, wherein a refractive index of the third cover layer is in a range of about 1.05 to about 1.59.

11. The cover layer of claim 1, wherein the thickness of the third cover layer is in a range of about 32 nm to about 40 nm.

12. The cover layer of claim 1, wherein
a refractive index of the sapphire substrate is about 1.77,
a refractive index of the first cover layer is about 1.38,
a refractive index of the second cover layer is about 1.48, and
a refractive index of the third cover layer is about 1.32.

13. A display device comprising:
a light-emitting-element layer including a light emitting element emitting light; and
a cover layer disposed on the light-emitting-element layer,
wherein the cover layer includes:
a sapphire substrate;
a first cover layer disposed on the sapphire substrate, the first cover layer including MgF₂, the first cover layer having a thickness in a range of about 16 nm to about 26 nm;
a second cover layer disposed on the first cover layer, the second cover layer including Si₉Al₂O₁₀, the second cover layer having a thickness in a range of about 45 nm to about 70 nm; and
a third cover layer disposed on the second cover layer, the third cover layer including perfluorinated polyether (PEPE), the third cover layer having a thickness in a range of about 10 nm to about 45 nm.

14. The display device of claim 13, wherein a sum of the thicknesses of the first to third cover layers is in a range of about 80 nm to about 130 nm.

15. The display device of claim 13, wherein a refractive index of the sapphire substrate is in a range of about 1.60 to about 1.95.

16. The display device of claim 13, wherein the cover layer has a transmittance of at least about 92% for 550 nm light and a reflectivity of less than about 8.50% for 550 nm light.
